(19) United States
(12) Patent Application Publication
(10) Pub. No.: US 2013/0277513 A1
(43) Pub. Date: Oct. 24, 2013

(54) HARD DISK BRACKET

(71) Applicants: Yung-Tai Pan, Taipei (TW); Shang-Hao Su, Taipei (TW)

(72) Inventors: Yung-Tai Pan, Taipei (TW); Shang-Hao Su, Taipei (TW)

(73) Assignee: PRIMAX ELECTRONICS LTD., Taipei (TW)

(21) Appl. No.: 13/554,718

(22) Filed: Jul. 20, 2012

(30) Foreign Application Priority Data
Apr. 20, 2012 (TW) 101114171

(51) Int. Cl. H05K 7/14

(52) U.S. Cl. 248/221.11

(57) ABSTRACT

A hard disc bracket is provided for fixing a hard disc within a computer case. The hard disc bracket includes a main frame and an auxiliary frame. The main frame has at least one opening. The auxiliary frame has at least one hook corresponding to the at least one opening and has at least one positioning post. After the auxiliary frame and the hard disc are combined together through the at least one positioning post, the at least one hook is engaged with the corresponding opening, so that the hard disc is fixed on the hard disc bracket. Consequently, the hard disc may be fixed on the hard disc bracket without the need of using a screwdriver or any other tool.

### FIELD OF THE INVENTION

The present invention relates to a bracket, and more particularly to a hard disc bracket for fixing a hard disc within a computer case.

### BACKGROUND OF THE INVENTION

With rapid development of electronic and information industries, computers and the peripheral device thereof become essential parts in our daily lives. In addition to the working purposes, computers can be employed as amusement tools. Generally, a computer comprises a display screen, a computer case, a motherboard, a hard disc, a microprocessor, a memory, and other components. Recently, the manufacturers of the computers pay much attention to these components and try to improve the outward appearance, performance and use lives of these components. In these components of the computer, the microprocessor and the memory are mounted on the motherboard, and the hard disc is fixed on the computer case.

Conventionally, the hard disc is directly fixed on the computer case by screwing means. For facilitating the user to remove the hard disc from the computer case, the hard disc may be firstly supported on a hard disc bracket, and then the hard disc bracket is stored within the computer case. In addition, the hard disc bracket is detachably connected to the computer case. By means of the hard disc bracket, the hard disc can be removed from the computer case or stored within the computer case more easily.

Hereinafter, the structure of a conventional hard disc bracket and a computer case will be illustrated with reference to FIG. 1. FIG. 1 is a schematic perspective view illustrating the relationship between a hard disc bracket, and a computer case according to the prior art. In FIG. 1, a hard disc bracket 1 and a computer case 2 are shown. The hard disc bracket 1 is used for accommodating a hard disc (not shown). In addition, the hard disc bracket 1 may be stored within the computer case 2. The hard disc bracket 1 comprises two lateral plates 10, a receiving space 11, and two locking elements 12. The receiving space 11 is used for accommodating the hard disc. After the hard disc is accommodated within the receiving space 11, the hard disc is fixed on the hard disc bracket 1 by screwing means. The computer case 2 comprises two sliding tracks 20 and two openings 21. The two sliding tracks 20 are located at two sides of the computer case 2. Since the two lateral plates 10 of the hard disc bracket 1 may be respectively slid along the two sliding tracks 20, the sliding tracks 20 can facilitate storing the hard disc bracket 1 within the computer case 2. The two openings 21 are located at first ends of the two sliding tracks 20, respectively.

A process of fixing the hard disc on the computer case 2 will be illustrated as follows. Firstly, the hard disc is accommodated within the receiving space 11 of the hard disc bracket 1. Then, the hard disc is fixed within the receiving space 11 by a plurality of screws (not shown). Then, the two lateral plates 10 of the hard disc bracket 1 are respectively aligned with the two sliding tracks 20 of the computer case 2, and the hard disc bracket 1 is pushed to be slid into the computer case 2 along the two sliding tracks 20. Then, the two locking elements 12 are rotated to have the first ends 121 of the locking elements 12 insert into corresponding openings 21 of the computer case 2. Consequently, the hard disc bracket 1 is in a locked state. Under this circumstance, the hard disc bracket 1 is fixed on the computer case 2.

On the other hand, a process of removing the hard disc from the computer case 2 will be illustrated as follows. Firstly, the two locking elements 12 are rotated to have the first ends 121 of the locking elements 12 detach from corresponding openings 21 of the computer case 2. Consequently, the operating state of the hard disc bracket 1 is switched from the locked state to a released state. Then, by pulling the two locking elements 12 in the direction distant from the computer case 2, the hard disc bracket 1 is removed from the computer case 2. Afterwards, a screwdriver or another tool is employed to loosen the screws, and thus the hard disc may be removed from the hard disc bracket 1.

From the above discussions, the conventional hard disc bracket 1 can be used to accommodate the hard disc. In addition, due to the structure of the conventional hard disc bracket 1, the hard disc bracket 1 with the hard disc may be directly stored within the computer case 2 or the hard disc bracket 1 with the hard disc may be removed from the computer case 2 without the need of using a screwdriver or any other tool to disassemble the hard disc from the computer case 2. However, when the user wants to remove the hard disc from the conventional hard disc bracket 1, the screwdriver or any other tool is required to loosen the screws in order to remove the hard disc.

Therefore, there is a need of providing an improved hard disc bracket, in which the hard disc is disassembled from or combined with the hard disc bracket without the need of using a screwdriver or any other tool.

### SUMMARY OF THE INVENTION

The present invention provides a hard disc bracket, in which the hard disc is disassembled from or combined with the hard disc bracket without the need of using a screwdriver or any other tool.

In accordance with an aspect of the present invention, there is provided a hard disc bracket for fixing a first hard disc within a computer case. The hard disc bracket includes a main frame and an auxiliary frame. The main frame has at least one first opening. The at least one first opening is located at a bottom part of the main frame. The auxiliary frame is disposed on the main frame and combined with the first hard disc. A combination of the auxiliary frame and the first hard disc is permitted to be fixed on the main frame. The auxiliary frame includes a first auxiliary frame lateral plate, at least one positioning post, and at least one first hook. The first auxiliary frame lateral plate may be contacted with a first sidewall of the first hard disc. The at least one positioning post is disposed on the first auxiliary frame lateral plate and inserted into the at least one perforation of the first hard disc. The at least one first hook is located at a lower edge of the first auxiliary frame lateral plate. When the at least one first hook is engaged with the at least one first opening of the main frame, the auxiliary frame is fixed on the main frame.

In an embodiment, the main frame further includes at least one main frame lateral plate, a positioning wall, and a receiving space. The at least one main frame lateral plate is located at a side of the main frame. The positioning wall is located at a first end of the main frame and connected with the at least one main frame lateral plate. The receiving space is used for accommodating the first hard disc and the auxiliary frame or accommodating the first hard disc, the auxiliary frame and a second hard disc. Moreover, the receiving space is defined by the bottom part of the main frame, the at least one main frame lateral plate and the positioning wall collaboratively.

In an embodiment, the positioning wall has at least one positioning rib, and the at least one positioning rib is disposed on an inner surface of the positioning wall. When the second hard disc is accommodated within the receiving space, the second hard disc is stopped by the at least one positioning rib from being slid relative to the main frame.

In an embodiment, the at least one positioning rib is extended from the positioning wall in a direction toward the receiving space. The at least one positioning rib is integrally formed with the positioning wall, the positioning wall is perpendicular to the at least one main frame lateral plate, and the positioning wall and the at least one main frame lateral plate are integrally formed with the main frame.

In an embodiment, the main frame further includes at least one stopper, and the at least one stopper is located at a second end of the main frame and connected with the at least one main frame lateral plate. When the second hard disc is accommodated within the receiving space, the second hard disc is stopped by the stopper from being slid relative to the main frame.

In an embodiment, the at least one stopper is perpendicular to the at least one main frame lateral plate, the at least one stopper is integrally formed with the at least one main frame lateral plate, and the at least one main frame lateral plate is integrally formed with the main frame.

In an embodiment, the main frame further includes at least one protrusion. The at least one protrusion is disposed on the bottom part of the main frame to be inserted into at least one second perforation of the first hard disc, and the at least one protrusion is extended from the bottom part of the main frame in a direction toward the receiving space. The at least one protrusion is perpendicular to the bottom part of the main frame, and the at least one protrusion is integrally formed with the main frame.

In an embodiment, the at least one first perforation is located at the first sidewall of the first hard disc, and the at least one second perforation is located at a backside of the first hard disc.

In an embodiment, the first hard disc is a 2.5-inch hard disc, and the second hard disc is a 3.5-inch hard disc.

In an embodiment, the auxiliary frame further includes a second auxiliary frame lateral plate and a second hook. The second auxiliary frame lateral plate is perpendicular to the first auxiliary frame lateral plate and connected with the first auxiliary frame lateral plate to be contacted with a second sidewall of the first hard disc. The second hook is located at a lower edge of the second auxiliary frame lateral plate. When the at least one first hook is engaged with a second opening of the main frame, the auxiliary frame is fixed on the main frame.

In an embodiment, the first auxiliary frame lateral plate, the at least one positioning post and the at least one first hook are integrally formed with the auxiliary frame, and the second auxiliary frame lateral plate and the second hook are also integrally formed with the auxiliary frame.

In an embodiment, the computer case includes an entrance/exit and a plurality of resilience sheets. The entrance/exit is located at an end of the computer case. The main frame of the hard disc bracket is permitted to be introduced into the computer case through the entrance/exit. These resilience sheets are located at bilateral sides of the computer case. When the frame is stored within the computer case, the plurality of resilience sheets are sustained against the frame, thereby preventing detachment of the frame from the computer case.

The above objects and advantages of the present invention will become more readily apparent to those ordinarily skilled in the art after reviewing the following detailed description and accompanying drawings, in which:

### BRIEF DESCRIPTION OF THE DRAWINGS

FIG. 1 is a schematic perspective view illustrating the relationship between a hard disc bracket and a computer case according to the prior art;

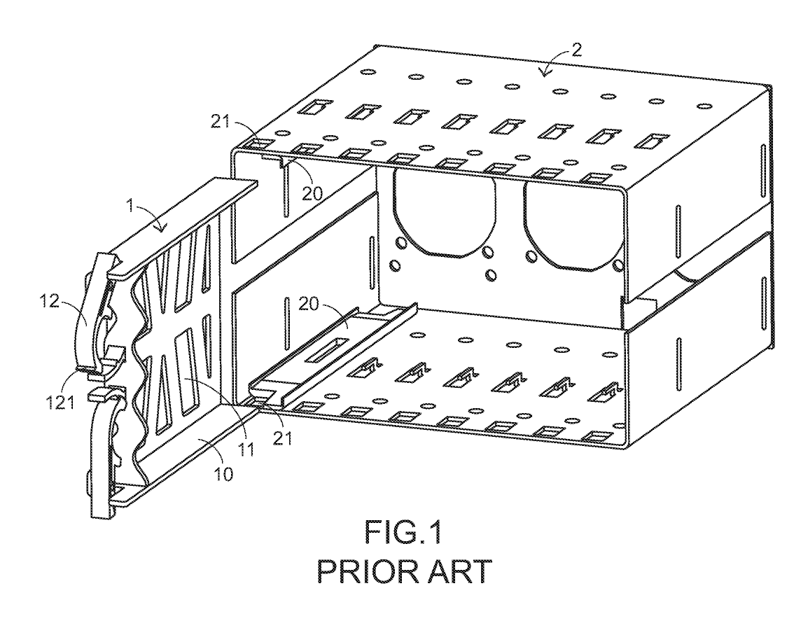

FIG. 2 is a schematic perspective view illustrating the relationship between a hard disc bracket, a hard disc and a computer case according to an embodiment of the present invention;

FIG. 3 is a schematic perspective view illustrating the relationship between an auxiliary frame of a hard disc bracket and a hard disc according to an embodiment of the present invention;

FIG. 4 is a schematic perspective view illustrating the relationship between a main frame of a hard disc bracket and a hard disc according to an embodiment of the present invention;

FIG. 5 is a schematic perspective view illustrating the alignment between an auxiliary frame and a main frame of a hard disc bracket according to an embodiment of the present invention;

FIG. 6 is a schematic assembled view of a hard disc bracket according to an embodiment of the present invention, in which the combination of the hard disc and the auxiliary frame is accommodated within the main frame;

FIG. 7 is a schematic perspective view illustrating the relationship between a hard disc bracket and two hard discs according to another embodiment of the present invention; and

FIG. 8 is a schematic cutaway view illustrating that the combination of the first hard disc and the auxiliary frame and the second hard disc are accommodated within the hard disc bracket according to an embodiment of the present invention.

### DETAILED DESCRIPTION OF THE PREFERRED EMBODIMENT

For obviating the drawbacks encountered from the prior art, the present invention provides a hard disc bracket.

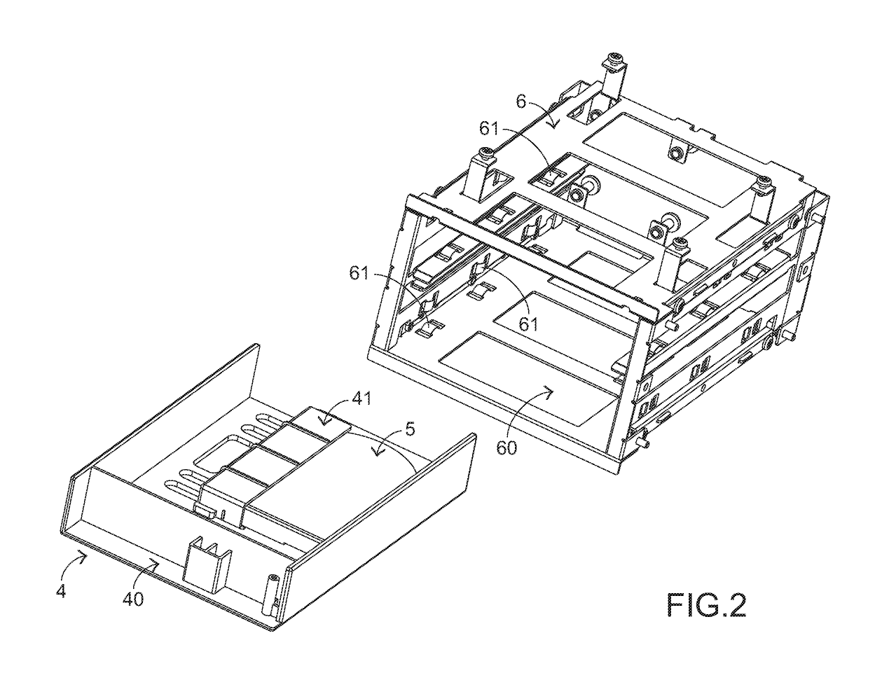

FIG. 2 is a schematic perspective view illustrating the relationship between a hard disc bracket, a hard disc and a computer case according to an embodiment of the present invention. In FIG. 2, a hard disc bracket 4, a hard disc 5 and a computer case 6 are shown. The hard disc bracket 4 comprises a main frame 40 and an auxiliary frame 41. The main frame 40 is used for supporting the hard disc 5. In addition, the main frame 40 may be accommodated within the computer case 6. The auxiliary frame 41 is disposed on the main frame 40. After the auxiliary frame 41 is combined with the hard disc 5, the hard disc 5 is fixed on the main frame 40. In this embodiment, the hard disc 5 is a 2.5-inch hard disc. As shown in FIG. 2, the computer case 6 comprises an entrance/exit 60 and a plurality of resilience sheets 61. The entrance/exit 60 is located at a front end of the computer case 6. Through the entrance/exit 60, the hard disc bracket 4 may be introduced into the computer case 6. The resilience sheets 61 are disposed within the computer case 6, and located at the bilateral sides of the computer case 6. After the main frame 40 is stored within the computer case 6, the resilience sheets 61 are sustained against the main frame 40 in order to avoid detachment of the main frame 40 from the computer case 6.

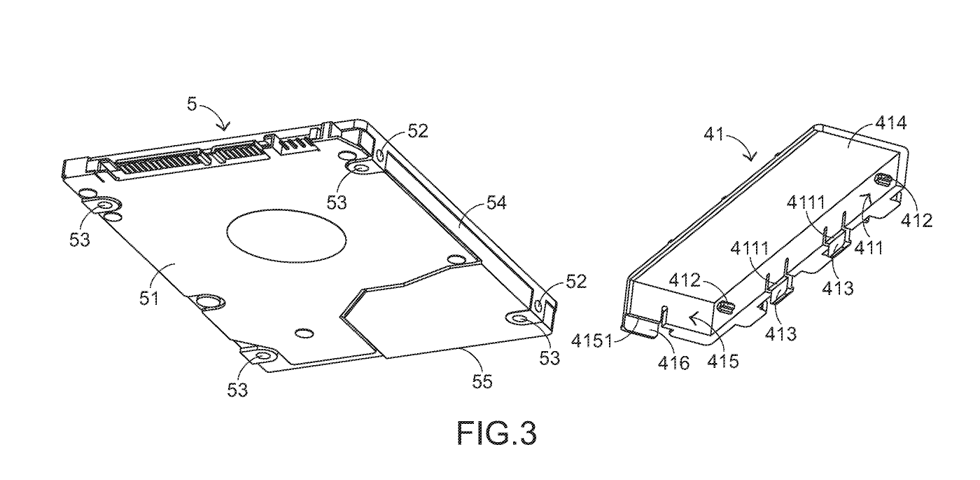

Hereinafter, the structures of the auxiliary frame 41 of the hard disc bracket 4 and the hard disc 5 will be illustrated with reference to FIG. 3. FIG. 3 is a schematic perspective view illustrating the relationship between an auxiliary frame of a hard disc bracket and a hard disc according to an embodiment of the present invention. In FIG. 3, a backside 51 of the hard disc 5 is shown. The hard disc 5 has at least one first perforation 52 (e.g. two first perforations 52 as shown in FIG. 3) and at least one second perforation 53 (e.g. four second perforation 53 as shown in FIG. 3). The at least one first perforation 52 is located at a first sidewall 54 of the hard disc. The at least one second perforation 53 is located at the backside 51 of the hard disc 5.

Please refer to FIG. 3 again. The auxiliary frame 41 comprises a first auxiliary frame lateral plate 411, at least one positioning post 412 (e.g. two positioning posts 412 as shown in FIG. 3), at least one first hook 413 (e.g. two first hooks 413 as shown in FIG. 3), an upper cover 414, a second auxiliary frame lateral plate 415, and a second hook 416. The first auxiliary frame lateral plate 411 may be contacted with the first sidewall 54 of hard disc 5. The two positioning posts 412 are disposed on an inner wall of the first auxiliary frame lateral plate 411. After the two positioning posts 412 are inserted into two corresponding first perforations 52 of the hard disc 5, the hard disc 5 may be fixed on the auxiliary frame 41. The second auxiliary frame lateral plate 415 is perpendicular to the first auxiliary frame lateral plate 411, and connected with the first auxiliary frame lateral plate 411. That is, the first auxiliary frame lateral plate 411 and the second auxiliary frame lateral plate 415 are collectively defined as an inverted L-shaped structure. The second auxiliary frame lateral plate 415 may be contacted with a second sidewall 55 of the hard disc 5. The two first hooks 413 are located at a lower edge 4111 of the first auxiliary frame lateral plate 411. The second hook 416 is located a lower edge 4151 of the second auxiliary frame lateral plate 415. The upper cover 414 is connected with the first auxiliary frame lateral plate 411 and the second auxiliary frame lateral plate 415 in order to enhance the structural strength of the auxiliary frame 41.

In this embodiment, the first auxiliary frame lateral plate 411, the two positioning posts 412, the two first hooks 413, the upper cover 414, the second auxiliary frame lateral plate 415 and the second hook 416 are integrally formed with the auxiliary frame 41. Moreover, the auxiliary frame 41 is made of plastic material. Consequently, the two first hooks 413 and the second hook 416 have flexibility. Due to the flexibility, the two first hooks 413 and the second hook 416 may be slightly and externally poked in response to an external force without being broken. In this embodiment, two positioning posts 412 are disposed on the first auxiliary frame lateral plate 411. It is noted that the number of the positioning posts 412 may be varied according to the practical requirements. For example, in some embodiments, one or more than two positioning posts are disposed on the first auxiliary frame lateral plate. Similarly, the number of the first hooks or the second hook may be varied according to the practical requirements.

Moreover, the first auxiliary frame lateral plate 411 is located at a first side of the auxiliary frame 41, the two positioning posts 412 are disposed on the first auxiliary frame lateral plate 411, and the two first perforations 52 are located at the first sidewall 54 of the hard disc 5. After the second sidewall 55 of the hard disc 5 is aligned with the second auxiliary frame lateral plate 415, the two positioning posts 412 and the corresponding first perforations 52 can be aligned with each other. Under this circumstance, the two positioning posts 412 can be inserted into the corresponding first perforations 52, and thus the hard disc 5 can be combined with the auxiliary frame 41. On the other hand, if the second sidewall 55 of the hard disc 5 is not aligned with the second auxiliary frame lateral plate 415, the two positioning posts 412 fail to be inserted into the corresponding first perforations 52. Under this circumstance, the hard disc 5 fails to be combined with the auxiliary frame 41. In other words, the two positioning posts 412 are inserted into the corresponding first perforations 52 of the hard disc 5 in a foolproof manner.

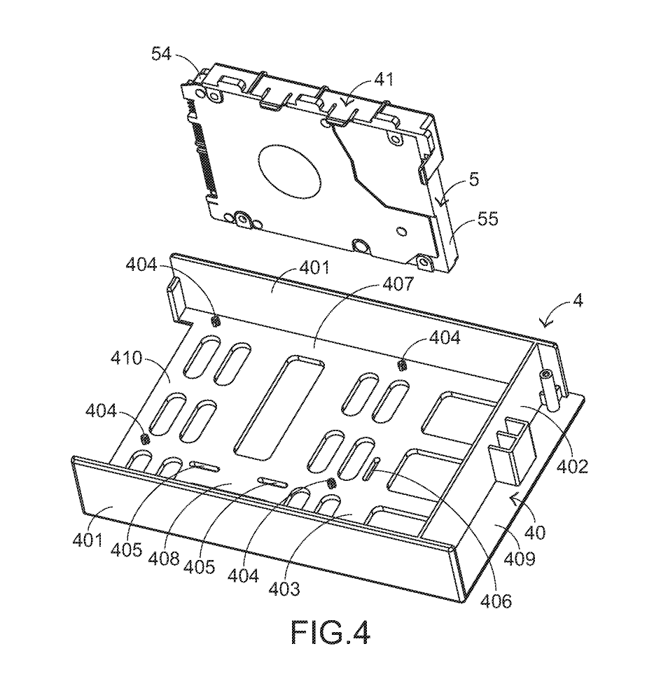

Hereinafter, the structure of the main frame 40 of the hard disc bracket 4 will be illustrated with reference to FIG. 4. FIG. 4 is a schematic perspective view illustrating the relationship between a main frame of a hard disc bracket and a hard disc according to an embodiment of the present invention. As shown in FIG. 4, the main frame 40 comprises two main frame lateral plates 401, a positioning wall 402, a receiving space 403, at least one protrusion 404 (e.g. four protrusions 404 as shown in FIG. 4), at least one first opening 405 (e.g. two first openings 405 as shown in FIG. 4), and a second opening 406. The two main frame lateral plates 401 are respectively located at a first side 407 and a second side 408 of the main frame 40 for avoiding detachment of the hard disc 5 from the main frame 40. The positioning wall 402 is located at a first end 409 of the main frame 40, and arranged between the two main frame lateral plates 401. Moreover, the positioning wall 402 is perpendicular to the two main frame lateral plates 401, and connected with the two main frame lateral plates 401. Consequently, the structural strength of the main frame 40 is enhanced. In this embodiment, the positioning wall 402 and the two main frame lateral plates 401 are integrally formed with the main frame 40.

The receiving space 403 of the main frame 40 is defined by a bottom part 410 of the main frame 40, the two main frame lateral plates 401 and the positioning wall 402 collaboratively. The receiving space 403 is used for accommodating the hard disc 5 and the auxiliary frame 41. The four protrusions 404 are disposed on the bottom part 410 of the main frame 40, and correspond to respective second perforation 53 of the hard disc 5, wherein two of the four protrusions 404 are located at the first side 407 of the main frame 40. Moreover, the four protrusions 404 are extended from the bottom part 410 of the main frame 40 in the direction toward the receiving space 403. The four protrusions 404 are all perpendicular to the bottom part 410 of the main frame 40, and inserted into corresponding second perforation 53 of the hard disc 5. In this embodiment, these protrusions 404 are integrally formed with the main frame 40. The two first openings 405 are located at the bottom part 410 of the main frame 40. After the two first hooks 413 of the auxiliary frame 41 are engaged with the corresponding first openings 405, the auxiliary frame 41 is fixed on the main frame 40. The second opening 406 is also located at the bottom part 410 of the main frame 40. The second hook 416 of the auxiliary frame 41 is engaged with the second opening 406. The engagement between the second opening 406 and the second opening 406 may assist in securely fixing the auxiliary frame 41 on the main frame 40. Since the two first openings 405 and the second opening 406 are respectively aligned with the two first hooks 413 and the second hook 416, the two first openings 405 and the second opening 406 are collectively in an inverted L-shaped arrangement.

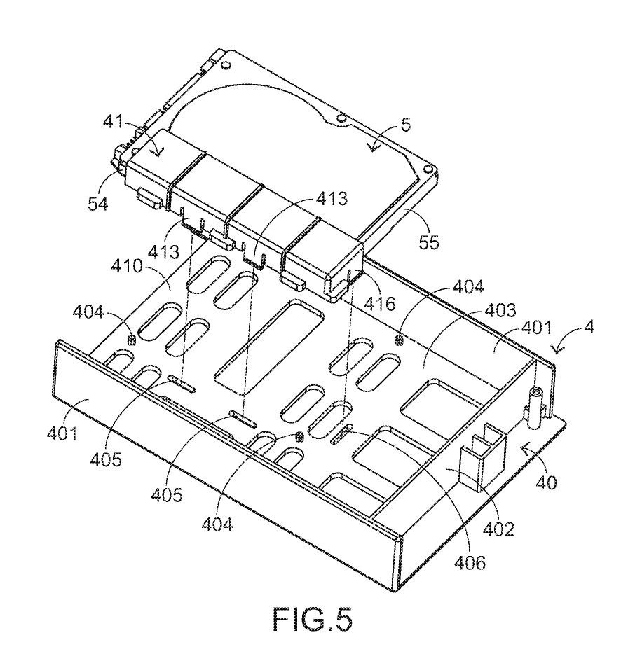

A process of accommodating and fixing the hard disc 5 within the receiving space 403 of the hard disc bracket 4 will be illustrated as follows. Please refer to FIG. 3 again. For combining the hard disc 5 and the auxiliary frame 41 together, the two first perforations 52 of the hard disc 5 should be aligned with corresponding positioning posts 412 of the auxiliary frame 41 before the hard disc 5 is accommodated within the receiving space 403. Moreover, after the two positioning posts 412 are inserted into the corresponding first perforations 52, the hard disc 5 and the auxiliary frame 41 can be securely combined together. Then, the combination of the hard disc 5 and the auxiliary frame 41 is moved to a region over the receiving space 403 of the main frame 40, and the four second perforations 53 at the backside 51 of the hard disc 5 are aligned with the four protrusions 404 at the bottom part 410 of the main frame 40. At the same time, the two first hooks 413 of the auxiliary frame 41 are aligned with the two first openings 405 at the bottom part 410 of the main frame 40, and the second hook 416 of the auxiliary frame 41 is aligned with the second opening 406 at the bottom part 410 of the main frame 40 (see FIG. 5).

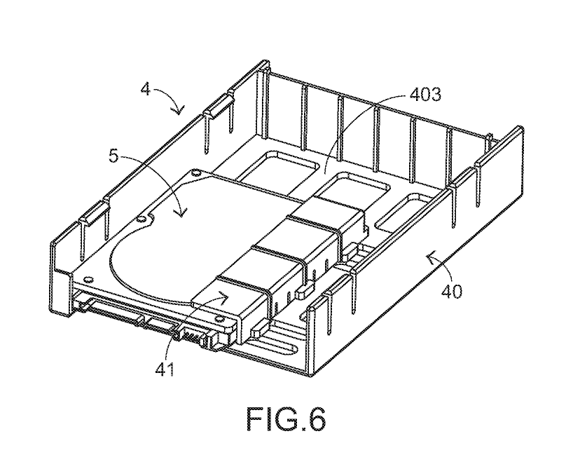

Afterwards, due to the flexibility of the first hooks 413 and the second hook 416, the two first hooks 413 may be respectively inserted into and engaged with the two first openings 405, and the second hook 416 may be inserted into and engaged with the second opening 406. In addition, the four protrusions 404 of the main frame 40 are inserted into the corresponding second perforation 53 of the hard disc 5 for assisting in fixing the auxiliary frame 41 and the hard disc 5 within the receiving space 403 of the main frame 40 (see FIG. 6).

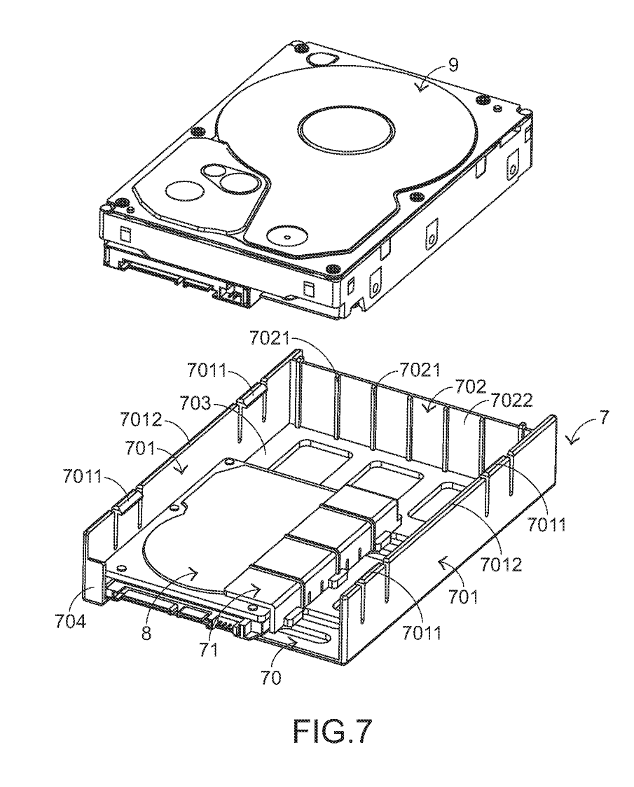

The present invention further provides another embodiment of a hard disc bracket. FIG. 7 is a schematic perspective view illustrating the relationship between a hard disc bracket and two hard discs according to another embodiment of the present invention. In FIG. 7, a hard disc bracket 7, a first hard disc 8 and a second hard disc 9 are shown. The hard disc bracket 7 comprises a main frame 70 and an auxiliary frame 71. The auxiliary frame 71 is disposed on the main frame 70. After the auxiliary frame 71 is combined with the first hard disc 8, the first hard disc 8 is fixed on the main frame 70. In this embodiment, the first hard disc 8 is a 2.5-inch hard disc, and the second hard disc 9 is a 3.5-inch hard disc.

The configurations of the auxiliary frame 71 and the first hard disc 8 are similar to those of the auxiliary frame 41 and the hard disc 5 of the above embodiment, and are not redundantly described herein. As shown in FIG. 7, the main frame 70 comprises two main frame lateral plates 701, a positioning wall 702, a receiving space 703, at least one protrusion (not shown), at least one first opening (not shown), a second opening (not shown), and a stopper 704. Except for the following three items, the configurations of the other components of the main frame 70 are similar to those of the main frame 40 of the above embodiment, and are not redundantly described herein.

Firstly, the main frame 70 is additionally equipped with the stopper 704. The stopper 704 is located at a second end of the main frame 70. In addition, the stopper 704 is perpendicular to the main frame lateral plates 701, and connected to one of the main frame lateral plates 701. When the second hard disc 9 is accommodated within the receiving space 703, the stopper 704 is in contact with the second hard disc 9 in order to stop the second hard disc 9 from being slid relative to the main frame 70 in the horizontal direction. In this embodiment, the stopper 704 is integrally formed with one of the main frame lateral plates 701, and the main frame lateral plates 701 are integrally formed with the main frame 70. Secondly, the positioning wall 702 has a plurality of positioning ribs 7021. These positioning ribs 7021 are formed on an inner surface 7022 of the positioning wall 702. When the second hard disc 9 is accommodated within the receiving space 703, the positioning ribs 7021 are in contact with the second hard disc 9 in order to stop the second hard disc 9 from being slid relative to the main frame 70 in the horizontal direction. These positioning ribs 7021 are extended from the positioning wall 702 in the direction toward the receiving space 703. In this embodiment, these positioning ribs 7021 are integrally formed with the positioning wall 702. The positioning wall 702 is perpendicular to the two main frame lateral plates 701. The positioning wall 702 and the two main frame lateral plates 701 are integrally formed with the main frame 70. Thirdly, each of the main frame lateral plates 701 has a plurality of third hooks 7011. The third hooks 7011 are located at an upper edge 7012 of the main frame lateral plate 701. After the second hard disc 9 is accommodated within the receiving space 703, the top peripheries of the second hard disc 9 are confined by the third hooks 7011. Consequently, the second hard disc 9 can be securely fixed on the main frame 70 without being escaped from the main frame 70 in the vertical direction. In this embodiment, these third hooks 7011 are integrally formed with the main frame lateral plates 701.

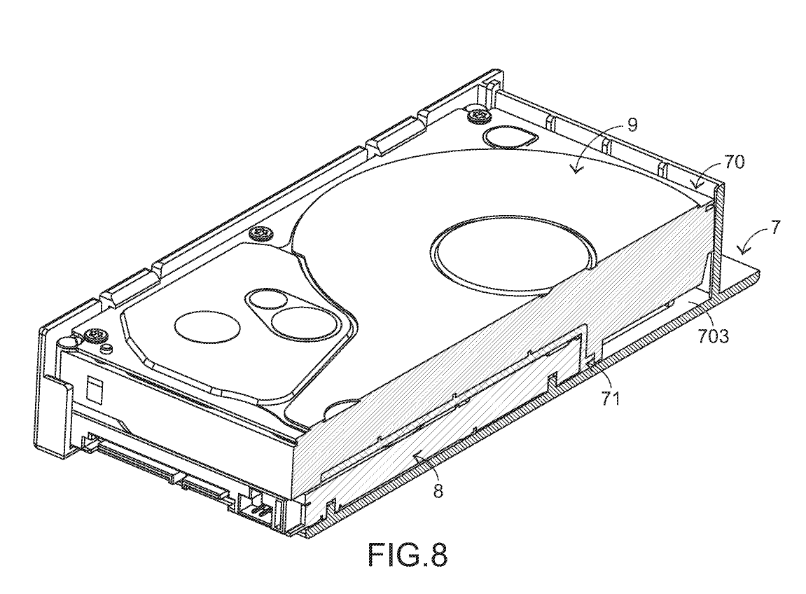

From the above discussions, the hard disc bracket 7 of this embodiment is capable of fixing the combination of the auxiliary frame 71 and the first hard disc 8 within the receiving space 703. Moreover, due to the additional components, the second hard disc 9 can be also fixed within the receiving space 703 along with the first hard disc 8. After the combination of the first hard disc 8 and the auxiliary frame 71 and the second hard disc 9 are accommodated within the receiving space 703 of the main frame 70, the resulting structure is shown in FIG. 8.

From the above description, the present invention provides a hard disc bracket with a main frame and an auxiliary frame. After the auxiliary frame of the hard disc bracket is combined with the hard disc through the positioning posts, the hooks of the auxiliary frame are engaged with corresponding openings of the main frame of the hard disc bracket. Consequently, the combination of the auxiliary frame and the hard disc is fixed within the receiving space of the main frame. Moreover, the uses of the protrusions, the positioning ribs, the third hooks and the stopper can assist in fixing the hard disc and another hard disc within the receiving space. Consequently, the hard disc may be fixed on the hard disc bracket without the screwing means. Since the hard disc is combined with or disassembled from the hard disc bracket without the need of using a screwdriver or any other tool, the convenience of assembling or disassembling the hard disc is enhanced.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A hard disc bracket for fixing a first hard disc within a computer case, said hard disc bracket comprising:
a main frame having at least one first opening, wherein the at least one first opening is located at a bottom part of said main frame; and
an auxiliary frame disposed on said main frame and combined with said first hard disc, wherein a combination of said auxiliary frame and said first hard disc is permitted to be fixed on said main frame, wherein said auxiliary frame comprises:
a first auxiliary frame lateral plate to be contacted with a first sidewall of said first hard disc;
at least one positioning post disposed on said first auxiliary frame lateral plate and inserted into said at least one perforation of said first hard disc; and
at least one first hook located at a lower edge of said first auxiliary frame lateral plate, wherein when said at least one first hook is engaged with said at least one first opening of said main frame, said auxiliary frame is fixed on said main frame.

2. The hard disc bracket according to claim 1, wherein said main frame further comprises:
at least one main frame lateral plate located at a side of said main frame;
a positioning wall located at a first end of said main frame and connected with said at least one main frame lateral plate; and
a receiving space for accommodating said first hard disc and said auxiliary frame or accommodating said first hard disc, said auxiliary frame and a second hard disc, wherein said receiving space is defined by said bottom part of said main frame, said at least one main frame lateral plate and said positioning wall collaboratively.

3. The hard disc bracket according to claim 2, wherein said positioning wall has at least one positioning rib, and the at least one positioning rib is disposed on an inner surface of said positioning wall, wherein when said second hard disc is accommodated within said receiving space, said second hard disc is stopped by said at least one positioning rib from being slid relative to said main frame.

4. The hard disc bracket according to claim 3, wherein said at least one positioning rib is extended from said positioning wall in a direction toward said receiving space, wherein said at least one positioning rib is integrally formed with said positioning wall, said positioning wall is perpendicular to said at least one main frame lateral plate, and said positioning wall and said at least one main frame lateral plate are integrally formed with said main frame.

5. The hard disc bracket according to claim 2, wherein said main frame further comprises at least one stopper, and the at least one stopper is located at a second end of said main frame and connected with said at least one main frame lateral plate, wherein when said second hard disc is accommodated within said receiving space, said second hard disc is stopped by said stopper from being slid relative to said main frame.

6. The hard disc bracket according to claim 5, wherein said at least one stopper is perpendicular to said at least one main frame lateral plate, said at least one stopper is integrally formed with said at least one main frame lateral plate, and said at least one main frame lateral plate is integrally formed with said main frame.

7. The hard disc bracket according to claim 2, wherein said main frame further comprises at least one protrusion, wherein said at least one protrusion is disposed on said bottom part of said main frame to be inserted into at least one second perforation of said first hard disc, and said at least one protrusion is extended from said bottom part of said main frame in a direction toward said receiving space, wherein said at least one protrusion is perpendicular to said bottom part of said main frame, and said at least one protrusion is integrally formed with said main frame.

8. The hard disc bracket according to claim 7, wherein said at least one first perforation is located at said first sidewall of said first hard disc, and said at least one second perforation is located at a backside of said first hard disc.

9. The hard disc bracket according to claim 2, wherein said first hard disc is a 2.5-inch hard disc, and said second hard disc is a 3.5-inch hard disc.

10. The hard disc bracket according to claim 1, wherein said auxiliary frame further comprises:
a second auxiliary frame lateral plate perpendicular to said first auxiliary frame lateral plate and connected with said first auxiliary frame lateral plate to be contacted with a second sidewall of said first hard disc; and
a second hook located at a lower edge of said second auxiliary frame lateral plate, wherein when said at least one first hook is engaged with a second opening of said main frame, said auxiliary frame is fixed on said main frame.

11. The hard disc bracket according to claim 10, wherein said first auxiliary frame lateral plate, said at least one positioning post and said at least one first hook are integrally formed with said auxiliary frame, and said second auxiliary frame lateral plate and said second hook are also integrally formed with said auxiliary frame.

12. The hard disc bracket according to claim 1, wherein said computer case comprises:
an entrance/exit located at an end of said computer case, wherein said main frame of said hard disc bracket is permitted to be introduced into said computer case through said entrance/exit; and
a plurality of resilience sheets, which are located at bilateral sides of said computer case, wherein when said frame is stored within said computer case, said plurality of resilience sheets are sustained against said frame, thereby preventing detachment of said frame from said computer case.
